(19) United States
(12) Patent Application Publication
(10) Pub. No.: US 2013/0193452 A1
(43) Pub. Date: Aug. 1, 2013

(54) LIGHT EMITTING DIODE SYSTEM AND METHODS RELATING THERETO

(71) Applicants: Deborah R. Gravely, Martinsville, VA (US); Michael J. Green, Cary, NC (US); Kurt Douglas Roberts, Raleigh, NC (US); Richard A. Wessel, Raleigh, NC (US)

(72) Inventors: Deborah R. Gravely, Martinsville, VA (US); Michael J. Green, Cary, NC (US); Kurt Douglas Roberts, Raleigh, NC (US); Richard A. Wessel, Raleigh, NC (US)

(73) Assignee: E.I. DU PONT DE NEMOURS AND COMPANY, Wilmington, DE (US)

(21) Appl. No.: 13/362,262

(22) Filed: Jan. 31, 2012

(51) Int. Cl. H01L 27/15

(52) U.S. Cl. 257/88; 257/E27.12

(57) ABSTRACT

A light emitting diode system is disclosed having a bent layered structure conformed to a least a portion of a self-supporting three dimensional heat sink and maintains a breakdown voltage from 150 to 350 V/micron. The bent layered structure has an electrical circuit, a dielectric layer and at least one LED package, LED chip on board or mixtures thereof attached to the electrical circuit. The dielectric layer is a polyimide derived from at least 70 mole percent aromatic dianhydride based upon total dianhydride content of the polyimide and at least 70 mole percent aromatic diamine based upon total diamine content of the polyimide.

### FIELD OF DISCLOSURE

The field of the invention is light emitting diode systems. More specifically light emitting diode systems for three dimensional lighting applications.

### BACKGROUND

U.S. 2009/0226656 A1 is directed to a multi-layered structure for use with a high power, light emitting diode system. The structure is at least semi-flexible and is exemplified as comprising an FR4 epoxy based material that may also include a layer of fiberglass. Typically these structures are not capable of maintaining the bend or keeping the position the structure is bent or twisted to form.

Therefore there is a need for light emitting diode systems for three dimensional lighting applications that have light design freedom and design for assembly or manufacture while maintaining electrical integrity.

### SUMMARY

The present disclosure is directed to a light emitting diode system comprising:
A) a bent layered structure consisting of:
   i. a electrical circuit having a thickness from 9 to 200 microns;
   ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
   iii. at least one LED package, LED chip on board or mixtures thereof attached to the electrical circuit and connected to at least one surface mount technology electrical component by the electrical circuit;
B) a self-supporting three dimensional heat sink;
C) a heat sink adhesive layer between the dielectric layer of the bent layered structure and the self-supporting three dimensional heat sink; and
wherein the bent layered structure is conformed to a least a portion of the self-supporting three dimensional heat sink and maintains a 150 to 350 V/micron breakdown voltage.

In another embodiment, the present disclosure is directed to a light emitting diode system comprising:
A) a bent layered structure consisting of:
   i. a electrical circuit having a thickness from 9 to 200 microns;
   ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
   iii. at least one LED package, LED chip on board or mixtures thereof attached to the electrical circuit and connected to at least one surface mount technology electrical component by the electrical circuit;
   iv. an adhesive layer between the electrical circuit and the dielectric layer;
B) a self-supporting three dimensional heat sink;
C) a heat sink adhesive layer between the dielectric layer of the bent layered structure and the self-supporting three dimensional heat sink; and
wherein the bent layered structure is conformed to a least a portion of the self-supporting three dimensional heat sink and maintains a 150 to 350 V/micron breakdown voltage.

In another embodiment, the present disclosure is directed to light emitting diode system comprising:
A) a bent layered structure consisting of:
   i. a electrical circuit having a thickness from 9 to 200 microns;
   ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
   iii. at least one LED package, LED chip on board or mixtures thereof attached to the electrical circuit and connected to at least one surface mount technology electrical component by the electrical circuit;
   iv. an adhesive layer between the electrical circuit and the dielectric layer;
   v. a coverlay on the bent layered structure wherein the coverlay is an acrylic photoimageable soldermask, epoxy photoimageable soldermask or a flexible coverlay with a coverlay adhesive;
B) a self-supporting three dimensional heat sink;
C) a heat sink adhesive layer between the dielectric layer of the bent layered structure and the self-supporting three dimensional heat sink; and
wherein the bent layered structure is conformed to at least a portion of the self-supporting three dimensional heat sink and maintains a 150 to 350 V/micron breakdown voltage.

### BRIEF DESCRIPTION OF THE DRAWINGS

FIG.1 illustrates the bend angle and radius as used in the present disclosure.

### DETAILED DESCRIPTION

### Definitions

“Bent” is intended to mean not straight or having at least one fold, arch, curve or the like and maintains such fold, arch, curve or the like.

“Film” is intended to mean a free-standing film or a (self-supporting or non self-supporting) coating and includes multiple layers. The term “film” is used interchangeably with the term “layer” or “multilayer” and refers to covering a desired area.

“Dianhydride” as used herein is intended to include precursors or derivatives thereof, which may not technically be a dianhydride but would nevertheless react with a diamine to form a polyamic acid which could in turn be converted into a polyimide.

“Diamine” as used herein is intended to include precursors or derivatives thereof, which may not technically be a diamine but would nevertheless react with a dianhydride to form a polyamic acid which could in turn be converted into a polyimide.

“Aromatic diamine” is intended to mean a diamine having at least one aromatic ring, either alone (i.e., a substituted or unsubstituted, functionalized or unfunctionalized benzene or similar-type aromatic ring) or connected to another (aromatic or aliphatic) ring, and such an diamine is to be deemed aromatic, regardless of any non-aromatic moieties that might also be a component of the diamine.

“Aromatic dianhydride” is intended to mean a dianhydride having at least one aromatic ring, either alone (i.e., a substituted or unsubstituted, functionalized or unfunctionalized benzene or similar-type aromatic ring) or connected to another (aromatic or aliphatic) ring, and such an dianhydride is to be deemed aromatic, regardless of any non-aromatic moieties that might also be a component of the dianhydride.

“Chemical conversion” or “chemically converted” as used herein denotes the use of a catalyst (accelerator) or dehydrating agent (or both) to convert the polyamic acid to polyimide and is intended to include a partially chemically converted polyimide which is then dried at elevated temperatures to a solids level greater than 98%.

In describing certain polymers it should be understood that sometimes applicants are referring to the polymers by the monomers used to make them or the amounts of the monomers used to make them. While such a description may not include the specific nomenclature used to describe the final polymer or may not contain product-by-process terminology, any such reference to monomers and amounts should be interpreted to mean that the polymer is made from those monomers, unless the context indicates or implies otherwise.

As used herein, the terms “comprises,” “comprising,” “includes,” “including,” “has,” “having” or any other variation thereof, are intended to cover a non-exclusive inclusion. For example, a method, process, article, or apparatus that comprises a list of elements is not necessarily limited to only those elements but may include other elements not expressly listed or inherent to such method, process, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, articles “a” or “an” are employed to describe elements and components of the invention. This is done merely for convenience and to give a general sense of the invention. This description should be read to include one or at least one and the singular also includes the plural unless it is obvious that it is meant otherwise.

The present disclosure is directed to light emitting diode (LED) system comprising a bent layered structure, consisting of an electrical circuit and a dielectric layer, conformed to a least a portion of a self-supporting three dimensional heat sink. The bent layered structure maintains a 150 to 350 V/micron breakdown voltage and is well suited for use as part of a high power (e.g., greater than 0.25, 0.5, 1, 2, 3, 4, 5, 8 10, 15, 20 or 25 watts per LED) light emitting diode system.

### Electrical Circuit

The electrical circuit can be formed by photolithography of a metal layer or any other method well known in the art. In some embodiments, the electrical circuit has a thickness between and including any two of the following: 9, 10, 15, 20, 30, 40, 50, 75, 100, 120, 140, 160, 180 and 200 microns. In some embodiments, the electrical circuit has a thickness is from 9 to 200 microns. The electrical circuit maintains its electrical integrity at bend angles of 45 degrees or greater. Although copper is a preferred conductive material, it is recognized that other suitable electrically conductive materials such as, but not limited to, aluminum could be used.

### Dielectric Layer

In some embodiments, the dielectric layer is a mechanically strong, heat resistant polymer, such as a polyester (such as polyethylene terephthalate or polybutylene terephthalate), fluoropolymer, acrylonitrile butadiene styrene (“ABS”), polycarbonates (“PC”), polyamides (“PA”), polyphenylene oxide (“PPO”), polysulphone (“PSU”), polyetherketone (“PEK”), polyetheretherketone (“PEEK”), polyphenylene sulfide (“PPS”), polyoxymethylene plastic (“POM”), polyethylene naphthalate (“PEN”), or the like.

In some embodiments, the dielectric layer is a polyimide. In some embodiments, the polyimide is derived from at least 70 mole percent aromatic dianhydride based upon total dianhydride content of the polyimide and at least 70 mole percent aromatic diamine based upon total diamine content of the polyimide. In some embodiments, the dielectric layer comprises 50 to 99 weight percent of a polyimide. In some embodiments, the dielectric layer comprises a polyimide present in an amount between and including any two of the following: 50, 55, 60, 65, 70, 75, 80, 85, 90, 95 and 99 weight percent based on the total weight of the dielectric layer. In another embodiment, the polyimide is derived from at least 100 mole percent aromatic dianhydride based upon total dianhydride content of the polyimide and at least 100 mole percent aromatic diamine based upon total diamine content of the polyimide. In some embodiments, the aromatic dianhydride and aromatic diamine can be mixtures of aromatic dianhydrides and mixtures of aromatic diamines. Useful aromatic dianhydrides include, (but are not limited to) pyromellitic dianhydride (PMDA); 3,3′,4,4′-biphenyl tetracarboxylic dianhydride (BPDA); 3,3′,4,4′-benzophenone tetracarboxylic dianhydride (BTDA); 4,4′-oxydiphthalic anhydride (ODPA); 3,3′,4,4′-diphenylsulfone tetracarboxylic dianhydride (DSDA); 2,2-bis(3,4-dicarboxyphenyl) 1,1,1,3,3,3-hexafluoropropane dianhydride (6FDA); 4,4′-(4,4′-isopropylidenediphenoxy)bis(phthalic anhydride) (BPADA); 2,3,6,7-naphthalene tetracarboxylic dianhydride; 1,2,5,6-naphthalene tetracarboxylic dianhydride; 1,4,5,8-naphthalene tetracarboxylic dianhydride; 2,3,3′,4′-biphenyl tetracarboxylic dianhydride; 2,2′,3,3′-biphenyl tetracarboxylic dianhydride; 2,3,3′,4′-benzophenone tetracarboxylic dianhydride; 2,2′,3,3′-benzophenone tetracarboxylic dianhydride; 2,2-bis(3,4-dicarboxyphenyl)propane dianhydride; 1,1-bis(2,3-dicarboxyphenyl)ethane dianhydride; 1,1-bis(3,4-dicarboxyphenyl)ethane dianhydride; bis-(2,3-dicarboxyphenyl)methane dianhydride and derivatives thereof.

Useful aromatic diamines include, (but are not limited to) 2,2 bis-(4-aminophenyl)propane; 4,4′-diaminodiphenyl methane; 4,4′-diaminodiphenyl sulfide; 3,3′-diaminodiphenyl sulfone (3,3′-DDS); 4,4′-diaminodiphenyl sulfone (4,4′-DDS); 4,4′-diaminodiphenyl ether (4,4′-ODA); 3,4′-diaminodiphenyl ether (3,4′-ODA); 1,3-bis-(4-aminophenoxy)benzene (APB-134 or RODA); 1,3-bis-(3-aminophenoxy)benzene (APB-133); 1,2-bis-(4-aminophenoxy)benzene; 1,5-diaminonaphthalene; 1,8-diaminonaphthalene; 1,2-diaminobenzene (OPD); 1,3-diaminobenzene (MPD); paraphenylene diamine (PPD); 2,5-dimethyl-1,4-diaminobenzene; 4,4′-diaminobenzophenone; 2,6-diaminotoluene; 3,3′-diaminodiphenylether and derivatives thereof.

In one embodiment, the polyimide is derived from pyromellitic dianhydride, 3,3′,4,4′-biphenyl tetracarboxylic dianhydride, 4,4′-diaminodiphenyl ether and paraphenylene diamine. In another embodiment, the polyimide is derived from 3,3′,4,4′-benzophenone tetracarboxylic dianhydride, 3,3′,4,4′-biphenyl tetracarboxylic dianhydride, 4,4′-diaminodiphenyl ether and paraphenylene diamine. In yet another embodiment, the polyimide is derived from pyromellitic dianhydride and 4,4′-diaminodiphenyl ether.

In some embodiments, the dielectric layer has a thickness from 1 to 100 microns. In some embodiments, the dielectric layer has a thickness between and including any two of the following: 1, 5, 10, 20, 30, 40, 50, 60, 70, 80, 90 and 100 microns. The dielectric layer can be of virtually any width or length.

In some embodiments, up to 30 percent of the total diamine may be an aliphatic diamine. As used herein, an “aliphatic diamine” is intended to mean any organic diamine that does not meet the definition of an aromatic diamine. In one embodiment, useful aliphatic diamines have the following structural formula: H₂N—R—NH₂, where R is an aliphatic moiety, such as a substituted or unsubstituted hydrocarbon in a range from 4, 5, 6, 7 or 8 carbons to about 9, 10, 11, 12, 13, 14, 15, or 16 carbon atoms, and in one embodiment the aliphatic moiety is a C₆ to C₈ aliphatic such as 1,6-hexamethylene diamine, 1,7-heptamethylene diamine, 1,8-octamethylenediamine. In some embodiments, up to 30 percent of the total dianhydride may be an aliphatic dianhydride such as, propionic, butyric, valeric and cyclobutane dianhydride

In one embodiment of the present invention (in order to achieve a low temperature bonding) diamines comprising ether linkages and or diamines comprising aliphatic functional groups are used. The term low temperature bonding is intended to mean bonding two materials in a temperature range of from about 180, 185, or 190° C. to about 195, 200, 205, 210, 215, 220, 225, 230, 235, 240, 245 or 250° C.

In some embodiments, the aromatic dianhydride or the aromatic diamine can be functionalized with one or more moieties, depending upon the particular embodiment selected in the practice of the present invention.

In some embodiments, the dielectric layer comprises a thermally conductive filler. In one embodiment, the dielectric layer comprises from 1 to 50 weight percent thermally conductive filler. In one embodiment, the dielectric layer comprises thermally conductive filler present in an amount between and including any two of the following: 1, 5, 10, 15, 20, 25, 30, 35, 40, 45 and 50 weight percent. The thermally conductive filler is selected from the group consisting of carbides, nitrides, borides and oxides. The filled polyimide will tend to have lower thermal resistance, thereby generally allowing more dissipation of unwanted heat. In one embodiment, the polyimide film of the present disclosure comprises a thermally conductive filler:
1. being less than 5 microns (and in some embodiments, less than 2000, 1000, 800, or 500 nanometers in at least one dimension (since thermally conductive fillers can have a variety of shapes in any dimension and since thermally conductive filler shape can vary along any dimension, the “at least one dimension” is intended to be a numerical average along that dimension);
2. having an average aspect ratio equal to or greater than 1, 2, 3, 4, 5, 6, 7, 8, 9, 10, 11, 12, 13, 14, or 15 to 1;
3. being less than 100, 95, 90, 85, 80, 75, 70, 65, 60, 55, 50, 45, 40, 35, 30, 25, 20, 15 or 10 percent of the film thickness in all dimensions.

Suitable thermally conductive fillers are generally stable at temperatures above 300, 350, 400, 425 or 450° C., and in some embodiments do not significantly decrease the electrical insulation properties of the film. In some embodiments, the thermally conductive filler is selected from a group consisting of needle-like thermally conductive fillers (acicular), fibrous thermally conductive fillers, platelet thermally conductive fillers and mixtures thereof. In one embodiment, the thermally conductive filler is substantially non-aggregated. The thermally conductive filler can be hollow, porous, or solid.

In some embodiments, the thermally conductive filler is selected from the group consisting of oxides (e.g., oxides comprising silicon, magnesium and/or aluminum), nitrides (e.g., nitrides comprising boron and/or silicon), carbides (e.g., carbides comprising tungsten and/or silicon), borides (e.g., titanium diboride) and combinations thereof. In some embodiments, the thermally conductive filler comprises titanium dioxide, talc, SiC, Al₂O₃ or mixtures thereof. In some embodiments, the thermally conductive filler is less than (as a numerical average) 50, 25, 20, 15, 12, 10, 8, 6, 5, 4, 2, 0.5 or 0.25 microns in all dimensions. In some embodiments, the thermally conductive filler is a sub-micron thermally conductive filler. Sub-micron is intended to describe particles having (as a numerical average) at least one dimension that is less than a micron.

In yet another embodiment, carbon fiber and graphite can be used in combination with thermally conductive fillers to increase mechanical properties. However in one embodiment, the loading of graphite, carbon fiber and/or electrically conductive fillers may need to be below the percolation threshold (perhaps less than 10 volume percent), since graphite and carbon fiber can diminish electrical insulation properties and in some embodiments, diminished electrical insulation properties are not desirable. In yet another embodiment, low amounts of carbon fiber and graphite may be used in combination with other fillers.

In some embodiments, the thermally conductive filler is coated with a coupling agent. In some embodiments, the thermally conductive filler is coated with an aminosilane coupling agent. In some embodiments, the thermally conductive filler is coated with a dispersant. In some embodiments, the thermally conductive filler is coated with a combination of a coupling agent and a dispersant. In some embodiments, the thermally conductive filler is coated with a coupling agent, a dispersant or a combination thereof. Alternatively, the coupling agent and/or dispersant can be incorporated directly into the film and not necessarily coated onto the thermally conductive filler. In some embodiments, the thermally conductive filler comprises acicular titanium dioxide, at least a portion of which is coated with an aluminum oxide.

In some embodiments, the thermally conductive filler is chosen so that it does not itself degrade or produce off-gasses at the desired processing temperatures. Likewise in some embodiments, the thermally conductive filler is chosen so that it does not contribute to degradation of the polymer.

In one embodiment, thermally conductive filler composites (e,g. single or multiple core/shell structures) can be used, in which one oxide encapsulates another oxide in one particle. In some embodiments, the thermally conductive filler is selected from the group consisting of spherical or near spherical shaped fillers, platelet-shaped fillers, needle-like fillers, fibrous fillers and mixtures thereof. In some embodiments, the platelet-shaped fillers and needle-like fillers and fibrous fillers will maintain or lower the CTE of the polyimide layer while still increasing the storage modulus. Useful fillers should be stable at temperatures of at least 105° C.) and not substantially decrease the electrical insulation of the polyimide film. In some embodiments, the thermally conductive filler is selected from the group consisting of mica, talc, boron nitride, wollastonite, clays, calcinated clays, silica, alumina, platelet alumina, glass flake, glass fiber and mixtures thereof. The thermally conductive filler may be treated or untreated.

In some embodiments, the thermally conductive filler is selected from a group consisting of oxides (e.g., oxides comprising silicon, titanium, magnesium and/or aluminum), nitrides (e,g., nitrides comprising boron and/or silicon), carbides (e.g., carbides comprising tungsten and/or silicon) and mixtures thereof. In some embodiments, the thermally conductive filler comprises oxygen and at least one member of the group consisting of aluminum, silicon, titanium, magnesium and combinations thereof. In some embodiments, the thermally conductive filler comprises platelet talc, acicular titanium dioxide, and/or acicular titanium dioxide, at least a portion of which is coated with an aluminum oxide.

Depending on the particular filler used, too low a filler loading may have minimal impact on the film properties, while too high a filler loading may cause the polyimide to become brittle. Ordinary skill and experimentation may be necessary in selecting any particular filler in accordance with the present disclosure, depending upon the particular application selected.

The polyimides of the present disclosure can be made by methods well known in the art. In one embodiment, the polyamic acids are made by dissolving approximately equimolar amounts of a dianhydride and a diamine in a solvent and agitating the resulting solution under controlled temperature conditions until polymerization of the dianhydride and the diamine is completed. Typically a slight excess of one of the monomers (usually diamine) is used to initially control the molecular weight and viscosity which can then be increased later via small additional amounts of the deficient monomer.

Ultimately, the precursor (polyamic acid) is converted into a high-temperature polyimide material having a solids content greater than about 99.5 weight percent. At some point in the process, the viscosity of the mixture is increased beyond the point where the thermally conductive filler material can be blended with the polyimide precursor. Depending upon the particular embodiment herein, the viscosity of the mixture can possibly be lowered again by diluting the material, perhaps sufficiently enough to allow dispersion of the thermally conductive filler material into the polyimide precursor.

Polyamic acid solutions can be converted to polyimides using processes and techniques commonly known in the art, such as, thermal or chemical conversion. Such polyimide manufacturing processes are well known. Any conventional or non-conventional polyimide manufacturing process can be appropriate for use in accordance with the present invention provided that a precursor material is available having a sufficiently low viscosity to allow thermally conductive filler material to be mixed. Likewise, if the polyimide is soluble in its fully imidized state, thermally conductive filler can be dispersed at this stage prior to forming into the final composite or can be added to the polyamic acid prior to imidization to thereby create a filled polyimide.

In some embodiments, the dielectric layer comprises a thermally stable reinforcing fabric, paper, sheet, scrim and combinations thereof in order to increase the storage modulus of the polyimide.

The polyimides of the present disclosure should have high thermal stability so that they do not substantially degrade, lose weight and exhibit diminished mechanical properties, as well as, do not give off significant volatiles during the deposition process. Aromatic polyimides have higher thermal stability than non-aromatic polyimides which is why it is desirable to use polyimides that have at least 70 mole percent aromatic dianhydride based upon total dianhydride content of the polyimide and at least 70 mole percent aromatic diamine based upon total diamine content of the polyimide. In some embodiments, the polyimide has an isothermal weight loss of less than 1% at 500° C. over 30 minutes under inert conditions in accordance with ASTM D3850.

Polyimides of the present disclosure have high dielectric strength.

In some embodiments, the dielectric strength of polyimides is much higher compared to common inorganic insulators. In some embodiments, dielectric layer of the present disclosure is a polyimide having a dielectric strength greater than 39.4 KV/mm. In some embodiments, dielectric layer of the present disclosure is a polyimide having a dielectric strength greater than 213 KV/mm.

The bent layered structure can be pre-populated with a plurality of LEDs (LED packages. LED chip on board) and other Surface Mount Technology (hereinafter “SMT”) electrical components well known in the art for completion of a solid state lighting electrical circuit cable of producing light. An example of a pre-populated bent layered structure could include, a plurality of LEDs positioned longitudinally along the circuit approximately every few centimeters, high current LED drivers positioned longitudinally between every sixth LED and seventh LED, and connectors for power placed longitudinally approximately every meter. An example of a suitable LED is CREE® XLAMP® XP-E manufactured by CREE® Incorporated of Raleigh, N.C. An example of a suitable high current LED driver is NUD4001 manufactured by ON SEMICONDUCTOR® of Phoenix, Ariz. In some embodiments the LEDs are connected prior to the bent structure being bent or after.

The bent layered structure is designed in such a way as to provide receptacles and mounting surfaces for LEDs and other surface mount technology (SMT) electrical components proximate the top surface (surface furthest away from the self-supporting three dimensional heat sink). The bent layered structure includes a plurality of LED receptacles to which LEDs are operatively connected. The electrical circuit and the LED receptacles can be made of copper and receive a lead free hot air solder level (HASL) or organic solder protection (OSP) coating. These coatings protect the electrical circuit surface from oxidization during storage, prior to assembly, enhancing solderability of SMT components. The placement of notches, receptacles, mounting surfaces for LEDs or other surface mount technology electrical components will be dependent on the desired structure of the bent layered structure and placement of LEDs.

In one embodiment, at least two high power LEDs are soldered onto LED receptacles on the electrical circuit of the bent layered structure. When electrical current is passed through the electrical circuit, the LEDs facing different directions are energized and emit visible light.

In some embodiments, the bent layered structure consists of:
i. a electrical circuit having a thickness from 9 to 200 microns;
ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns: and
iii. at least one LED package, LED chip on board or mixtures thereof attached to the electrical circuit and connected to at least one surface mount technology electrical component by the electrical circuit.

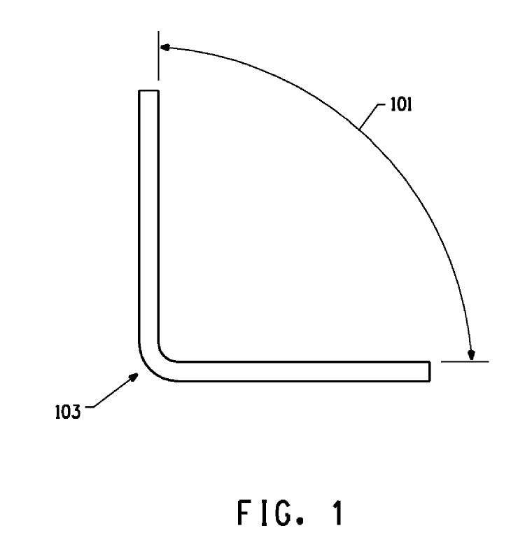

In one embodiment, the bent layered structure has multiple bends in order to conform to a least a portion of a self-supporting three dimensional heat sink. Each bend can have a radius of at least 2 mm and a bend angle of at least 45 degrees and the bent layered structure maintain a 150 to 350 V/micron breakdown voltage. FIG. 1 illustrates the radius 103 is the outside radius at a bend in the bent layered structure and the bend angle 101 is the angle inside the bent layered structure. In some embodiments, the bent layered structure has a radius of at least 2 mm and a bend angle of at least 45 degrees at least once along a longitudinal axis or at least once parallel to the longitudinal axis or both and maintains a 150 to 350 V/micron breakdown voltage. In some embodiments, the bent layered structure maintains a breakdown voltage of between and including any two of the following: 150, 200, 250, 300 and 350 V/micron. In some embodiments, the bent layered structure bend has a bend angle of at least 65 degrees at least once along a longitudinal axis or at least once parallel to the longitudinal axis or both and maintains a 150 to 350 V/micron breakdown voltage. In another embodiment, the bent layered structure has a bend angle of at least 90 degrees at least once along a longitudinal axis or at least once parallel to the longitudinal axis or both and maintains a 150 to 350 V/micron breakdown voltage. Typically, the break down voltage increases as the thickness of the dielectric layer increases. Thus, for a dielectric layer of the present disclosure having a thickness from 1 to 100 microns, a 150 to 350 V/microns breakdown voltage is maintained for a bent layered structure having a radius of at least 2 mm and a bend angle of at least 45 degrees at least once along a longitudinal axis or at least once parallel to the longitudinal axis or both.

The bent layered structure has a radius of at least 2 mm and a bend angle of at least 45 degrees once or multiple times and still maintains electrical integrity. The bent layered structure can have multiple bends along (down) the longitudinal axis or multiple bends parallel to the longitudinal axis resulting in a three dimensional configuration which then can be incorporated into a lighting structure. For example, one could envision a 3×3 array structure of LEDs having two longitudinal axes, one longitudinal axis between the first and second row of LEDs and a second longitudinal axis between the second and third row of LEDs. Such a structure could have one bend on one of the parallel axes or could have a bend on both parallel axes. The bent layered structure can have one or more bends along the length of the longitudinal axis and one or more bends parallel to the longitudinal axis creating complex three dimensional bent layered structures for LED lighting systems.

In some embodiments, the bent layered structure contains a plurality of notches to aid in bending. A notch is intended to mean any indentation into either the electrical circuit or dielectric layer whether by cutting, pressing, abrading, etching or otherwise.

In another embodiment, the bent layered structure consisting of:
i. an electrical circuit having a thickness from 9 to 200 microns;
ii. an dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
iii. at least one LED package, LED chip on board or mixtures thereof attached to the electrical circuit and connected to at least one surface mount technology electrical component by the electrical circuit; and
iv. an adhesive layer between the electrical circuit and the dielectric layer.

The adhesive layer can be any adhesive for bonding polyimide to metal. In one embodiment, the adhesive layer comprises a thermoplastic polyimide polymer comprising at least 20 mole percent aliphatic moieties and having a glass transition temperature below 350, 300, 250, 225, 200, 190, 180, 170, 160 or 150° C. In some embodiments, the adhesive layer is polyimide derived from 4,4′-oxydiphthalic anhydride, pyromellitic dianhydride and 1,3-bis-(4-aminophenoxy)benzene. In some embodiments, the adhesive layer can be a fluoropolymer, epoxy or acrylic adhesive. In some embodiments, the adhesive layer may improve bending capability with diminished necking, bulging or other unwanted incongruity otherwise induced by the bending of the layered structure. In some embodiments, the adhesive layer comprises a thermally conductive filler. In some embodiments, the thermally conductive filler in the adhesive layer is the same as the thermally conductive filler in the dielectric layer.

In some embodiments, the bent layered structure is coated with a protective coating (coverlay) using standard solder masking and labeling techniques well known in the art. Examples of coverlays that could be used are acrylic or epoxy photoimageable coverlays. In some embodiments, the coverlay is on the bent layered structure and the coverlay is an acrylic photoimageable soldermask, epoxy photoimageable soldermask or a flexible coverlay with a coverlay adhesive.

In one embodiment, a suitable coverlay can include brominated carboxylic copolymer binder comprising ring-brominated aromatic monomer units, alkyl acrylate, alkyl methacrylate or non-brominated aromatic monomer units and ethylenically unsaturated carboxylic acid monomer. Representative of ring-brominated aromatic monomers and non-brominated aromatic monomers are styrene, methylstyrene, alpha-methylstyrene, alpha-methyl methylstyrene, ethylstyrene or alpha-methyl ethylstyrene with bromine substitution (mono, di, tri and tetra) in the phenyl nucleus. Practical examples of the alkyl acrylate or alkyl methacrylate monomer unit are, but not limited to, methyl acrylate, ethyl acrylate, n-propyl acrylate, isopropyl acrylate, n-butyl acrylate, isobutyl acrylate, lauryl acrylate and the corresponding alkyl methacrylates. Practical examples of the ethylenically unsaturated monomer unit include acrylic acid, methacrylic acid, itaconic acid, maleic acid and fumaric acid.

In another embodiment, the bent layered structure consists of:
i. a electrical circuit having a thickness from 9 to 200 microns;
ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
iii. at least one LED package, LED chip on board or mixtures thereof attached to the electrical circuit and connected to at least one surface mount technology electrical component by the electrical circuit;
iv. an adhesive layer between the electrical circuit and the dielectric layer;
v. a coverlay on the bent layered structure wherein the coverlay is an acrylic photoimageable soldermask, epoxy photoimageable soldermask or a flexible coverlay with a coverlay adhesive.

In some embodiments, the bent layered structure may be made by casting a polyimide precursor onto a metal foil and heating so that the polyamic acid is converted to a polyimide. In another embodiment, the bent layered structure can also be formed by extrusion, co-extrusion, lamination or any other well-known method suitable for producing polyimide metal laminates. In another embodiment, electrical circuit can be laminated to an adhesive coated dielectric layer. In another embodiment, an adhesive coated electrical circuit can be laminated to the dielectric layer or to an adhesive coated dielectric layer.

Desired bend(s) can be accomplished with common metal fabrication techniques such as; air bending, bottoming, coining, v bending, u die bending, wipe die bending, double die bending, rotary bending, common brake or may be formed by hand.

### Self-Supporting Three Dimensional Heat Sink

When the bent layered structure is conformed to and in direct contact with at least a portion of the self-supporting three dimensional heat sink, heat transfer from the LEDs generally is improved.

The self-supporting three dimensional heat sink can be any shape. In some embodiments, the self-supporting three dimensional heat sink can be solid or plurality of separate self-supporting three dimensional heat sinks. In some embodiments, the self-supporting three dimensional heat sink can be part of a “screw in,” “plug in” or similar-type housing, so the final assembly can be configured as a replacement for a conventional light bulb. The self-supporting three dimensional heat sink can be made of any material that is thermally conductive. The heat sinks are typically composed of thermally conducting materials such as aluminum, anodized aluminum or thermally conductive polymers. Their construction can be as simple as a metal plate to a metal device with many fins. The high thermal conductivity of the metal combined with its large surface area result in the rapid transfer of thermal energy to the surrounding, cooler, air. This cools the heat sink and whatever it is in direct thermal contact with.

The light emitting diode system further comprising a heat sink adhesive layer between the dielectric layer of the bent layered structure and the self-supporting three dimensional heat sink. The heat sink adhesive layer can be any adhesive for bonding polyimide to metal. The heat sink adhesive layer can be a thermoplastic polymer, adhesive tapes, double-sided adhesive tapes, pressure sensitive adhesives and the like. In some embodiments, the heat sink adhesive layer can be a thermoplastic polyimide, fluoropolymer, epoxy or acrylic adhesive.

The self-supporting three dimensional heat sink is adhered to the bent layered structure by a heat sink adhesive layer. The heat sink adhesive layer can thereby provide thermal contact between the bent layered structure and the self-supporting three dimensional heat sink and the heat sink adhesive layer is optionally capable of filling large voids and air gaps to improve thermal conductivity.

An example of a suitable heat sink adhesive layer is two-sided thermally conductive tape, 3M® Thermally Conductive Adhesive Transfer Tape 8810. Other suitable thermally conductive connecting materials could be used.

In some embodiments, the heat sink adhesive layer is applied to the dielectric layer of the bent layered structure, by any suitable method, then pressed onto the self-supporting three dimensional heat sink. In some embodiments, the heat sink adhesive layer is applied to the self-supporting three dimensional heat sink, then the bent layered structure is pressed on to the self-supporting three dimensional heat sink. In some embodiments, the heat sink adhesive layer is applied to both the dielectric layer of the bent layered structure and the self-supporting three dimensional heat sink, then adhered together typically by pressure.

The bent layered structure is placed in the desired location on the self-supporting three dimensional heat sink, and pressure is applied onto the bent layered structure proximate the dielectric layer avoiding any sensitive electrical circuits and electric components (if applicable). In one embodiment, standard electro static discharge (“ESD”) precautions should be followed. In some embodiments, direct pressure should not be applied to pressure sensitive devices, such as LEDs with optical components. In one embodiment, manual pressure with one's finger(s) of approximately 13.8 kilo-Newtons/square meter) along 90% or more of the flexible layered structure should be sufficient for connection to the heat sink. In some embodiments, a roller or other applicator device could also be used. In one embodiment, once the flexible layered structure is connected to a heat sink, the electrical circuit can be connected to a termination board, which supplies power to the system as is well known in the art. If a heat sink adhesive layer is not used, the bent layered structure could be connected with thermal paste adhesive, thermal grease with mechanical fastening, or other suitable securing means.

In some embodiments the heat sink adhesive layer comprises a thermally conductive filler. The thermally conductive filler may be the same or different from the thermally conductive filler in the dielectric layer and the thermally conductive filler in the adhesive layer between the electrical circuit and the dielectric layer.

The light emitting diode systems of the present disclosure have design freedom, high heat dissipation, high breakdown voltages for LED lighting systems. In some embodiments, the light emitting diode systems of the present disclosure can be used in a replacement light for an A19 type light bulb. Other types of lights that could be adapted in accordance with the present disclosure are:

1. cove lights;

2. residential overhead lights;

3. linear lights;

4. rope lights;

5. accent lights;

6. projector lights;

7. stage bar lights;

8. par lamp lights;

9. linear lights;

10. color changer lights;

11. display case lights;

12. undercabinet lights;

13. backdrop lights;

14. accent lights;

15. refrigerated display case lights;

16. hazardous lights;

17. industrial fixture lights;

18. functional office lights;

19. down lights;

20. recessed lights;

21. roadway lights;

22. canopy lights;

23. area lights;

24. pole top lights;

25. solar flood lights;

26. lantern lights;

27. decorative suspended lights;

28. task lights;

29. flash light;

30. headlamps;

31. work lights; and

32. exit sign lights.

In some embodiment, the light emitting diode systems of the present disclosure may be used in any of the following types of replacement bulbs: A-lamp bulbs; PAR and R-Lamp bulbs; MR16 bulbs; candelabra bulbs or linear fluorescent bulbs

In some embodiments, the light emitting diode systems of the present disclosure may be used in automotive LED lighting such as, but not limited to, headlights, daylight running lights, side marker, rear tail-lights, fog lamps, cornering lamps and reverse lights.

What is claimed is:

1. A light emitting diode system comprising:
A) a bent layered structure consisting of:
i. a electrical circuit having a thickness from 9 to 200 microns;
ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
iii. at least one LED package, LED chip on board or mixtures thereof attached to the electrical circuit and connected to at least one surface mount technology electrical component by the electrical circuit;
B) a self-supporting three dimensional heat sink;
C) a heat sink adhesive layer between the dielectric layer of the bent layered structure and the self-supporting three dimensional heat sink; and
wherein the bent layered structure is conformed to a least a portion of the self-supporting three dimensional heat sink and maintains a 150 to 350 V/micron breakdown voltage.

2. The light emitting diode system in accordance with claim 1 wherein the polyimide is derived from at least 100 mole percent aromatic dianhydride based upon total dianhydride content of the polyimide and at least 100 mole percent aromatic diamine based upon total diamine content of the polyimide.

3. The light emitting diode system in accordance with claim 1 wherein the polyimide is derived from pyromellitic dianhydride, 3,3′,4,4′-biphenyl tetracarboxylic dianhydride, 4,4′-diaminodiphenyl ether and paraphenylene diamine.

4. The light emitting diode system in accordance with claim 1 wherein the polyimide is derived from 3,3′,4,4′-benzophenone tetracarboxylic dianhydride, 3,3′,4,4′-biphenyl tetracarboxylic dianhydride, 4,4′-diaminodiphenyl ether and paraphenylene diamine.

5. The light emitting diode system in accordance with claim 1 wherein the polyimide is derived from pyromellitic dianhydride and 4,4′-diaminodiphenyl ether.

6. The light emitting diode system in accordance with claim 1, wherein the dielectric layer comprises 1 to 50 weight percent thermally conductive filler, the thermally conductive filler is selected from the group consisting of carbides, nitrides, borides, oxides and mixtures thereof.

7. The light emitting diode system in accordance with claim 1, wherein the heat sink adhesive layer comprises a thermally conductive filler selected from the group consisting of carbides, nitrides, borides, oxides and mixtures thereof.

8. A light emitting diode system comprising:
A) a bent layered structure consisting of:
i. a electrical circuit having a thickness from 9 to 200 microns;
ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
iii. at least one LED package, LED chip on board or mixtures thereof attached to the electrical circuit and connected to at least one surface mount technology electrical component by the electrical circuit;
iv. an adhesive layer between the electrical circuit and the dielectric layer;
B) a self-supporting three dimensional heat sink;
C) a heat sink adhesive layer between the dielectric layer of the bent layered structure and the self-supporting three dimensional heat sink; and
wherein the bent layered structure is conformed to a least a portion of the self-supporting three dimensional heat sink and maintains a 150 to 350 V/micron breakdown voltage.

9. The light emitting diode system in accordance with claim 8 wherein the polyimide is derived from at least 100 mole percent aromatic dianhydride based upon total dianhydride content of the polyimide and at least 100 mole percent aromatic diamine based upon total diamine content of the polyimide.

10. The light emitting diode system in accordance with claim 8 wherein the polyimide is derived from pyromellitic dianhydride, 3,3′,4,4′-biphenyl tetracarboxylic dianhydride, 4,4′-diaminodiphenyl ether and paraphenylene diamine.

11. The light emitting diode system in accordance with claim 8 wherein the polyimide is derived from 3,3′,4,4′-benzophenone tetracarboxylic dianhydride, 3,3′,4,4′-biphenyl tetracarboxylic dianhydride, 4,4′-diaminodiphenyl ether and paraphenylene diamine.

12. The light emitting diode system in accordance with claim 8 wherein the polyimide is derived from pyromellitic dianhydride and 4,4′-diaminodiphenyl ether.

13. The light emitting diode system in accordance with claim 8, wherein the dielectric layer comprises 1 to 50 weight percent thermally conductive filler, the thermally conductive filler is selected from the group consisting of carbides, nitrides, borides, oxides and mixtures thereof.

14. The light emitting diode system in accordance with claim 8 wherein the heat sink adhesive layer and the adhesive layer between the electrical circuit and the dielectric layer both comprise a thermally conductive filler selected from the group consisting of carbides, nitrides, borides, oxides and mixtures thereof.

15. A light emitting diode system comprising:
A) a bent layered structure consisting of;
i. a electrical circuit having a thickness from 9 to 200 microns;
ii. a dielectric layer comprising a polyimide, the polyimide is derived from at least 70 mole percent aromatic dianhydride based upon total dianhydride content of the polyimide and at least 70 mole percent aromatic diamine based upon total diamine content of the polyimide, the dielectric layer having a thickness from 1 to 100 microns; and
iii. at least one LED package, LED chip on board or mixtures thereof attached to the electrical circuit and connected to at least one surface mount technology electrical component by the electrical circuit;
iv. an adhesive layer between the electrical circuit and the dielectric layer;
v. a coverlay on the bent layered structure wherein the coverlay is an acrylic photoimageable soldermask, epoxy photoimageable soldermask or a flexible coverlay with a coverlay adhesive;
B) a self-supporting three dimensional heat sink;
C) a heat sink adhesive layer between the dielectric layer of the bent layered structure and the self-supporting three dimensional heat sink; and
wherein the bent layered structure is conformed to a least a portion of the self-supporting three dimensional heat sink and maintains a 150 to 350 V/micron breakdown voltage.

16. The light emitting diode system in accordance with claim 15 wherein the polyimide is derived from at least 100 mole percent aromatic dianhydride based upon total dianhydride content of the polyimide and at least 100 mole percent aromatic diamine based upon total diamine content of the polyimide.

17. The light emitting diode system in accordance with claim 15 wherein the polyimide is derived from pyromellitic dianhydride, biphenyl tetracarboxylic dianhydride, 4,4′-diaminodiphenyl ether and paraphenylene diamine.

18. The light emitting diode system in accordance with claim 15 wherein the polyimide is derived from 3,3′,4,4′-benzophenone tetracarboxylic dianhydride, 3,3′,4,4′-biphenyl tetracarboxylic dianhydride, 4,4′-diaminodiphenyl ether and paraphenylene diamine.

19. The light emitting diode system in accordance with claim 15 wherein the polyimide is derived from pyromellitic dianhydride and 4,4′-diaminodiphenyl ether.

20. The light emitting diode system in accordance with claim 15, wherein the dielectric layer comprises 1 to 50 weight percent thermally conductive filler, the thermally conductive filler is selected from the group consisting of carbides, nitrides, borides, oxides and mixtures thereof.

21. The light emitting diode system in accordance with claim 15 wherein the heat sink adhesive layer and the adhesive layer between the electrical circuit and the dielectric layer both comprise a thermally conductive filler selected from the group consisting of carbides, nitrides, borides, oxides and mixtures thereof.
